(19) United States
(12) Patent Application Publication
(10) Pub. No.: US 2026/0251345 A1
(43) Pub. Date: Aug. 27, 2026

(54) AIR CONDITIONER

(71) Applicant: QINGDAO HISENSE HITACHI AIR-CONDITIONING SYSTEMS CO., LTD., Shandong (CN)

(72) Inventors: Moxuan YANG, Qingdao (CN); Fanggang CHAI, Qingdao (CN); Xiaoyu YANG, Qingdao (CN); Huazhen YAN, Qingdao (CN); Xiaodong ZHANG, Qingdao (CN); Chao JIANG, Qingdao (CN); Kai SUN, Qingdao (CN); Xiaofan WANG, Qingdao (CN); Xinzhou FAN, Qingdao (CN); Xu GUO, Qingdao (CN)

(73) Assignee: QINGDAO HISENSE HITACHI AIR-CONDITIONING SYSTEMS CO., LTD., Shandong (CN)

(21) Appl. No.: 19/645,256

(22) Filed: Apr. 12, 2026

Related U.S. Application Data
(63) Continuation of application No. PCT/CN2024/094996, filed on May 23, 2024.

(30) Foreign Application Priority Data
Mar. 1, 2024 (CN) 202410236593.5
Mar. 1, 2024 (CN) 202420398127.2
Mar. 1, 2024 (CN) 202420398140.8
Mar. 1, 2024 (CN) 202420398281.X
Mar. 1, 2024 (CN) 202420398331.4
Apr. 1, 2024 (CN) 202420655796.3
Apr. 1, 2024 (CN) 202420657719.1

(51) Int. Cl. F24F 13/22; F24F 1/0022; F24F 13/20

(52) U.S. Cl. CPC F24F 13/222; F24F 1/0022; F24F 13/20

(57) ABSTRACT

An air conditioner, comprising an outdoor unit and an indoor unit. The indoor unit comprises a casing, a heat exchange assembly, a fan and an electric control assembly. The casing comprises an air inlet and an air outlet. The heat exchange assembly comprises a heat exchanger and a condensate pan, the heat exchanger being configured to exchange heat with an airflow passing through same to form a heat-exchanged airflow, and the heat exchanger being provided at the top of the condensate pan. The fan is configured to introduce the airflow through the air inlet and send out same from the air outlet after the airflow passes through the heat exchanger. The electric control assembly comprises an electric control box and a circuit board, the circuit board being arranged in the electric control box.

### CROSS-REFERENCE TO RELATED APPLICATION

This application is a continuation of international patent application No. PCT/CN2024/094996 filed on May 23, 2024, which itself claims priority to Chinese Patent Application No. 202420398281.X filed on March 1, 2024, Chinese Patent Application No. 202420398331.4 filed on March 1, 2024, Chinese Patent Application No. 202420398140.8 filed on March 1, 2024, Chinese Patent Application No. 202420398127.2 filed on March 1, 2024, Chinese Patent Application No. 202410236593.5 filed on March 1, 2024, Chinese Patent Application No. 202420657719.1 filed on April 1, 2024, and Chinese Patent Application No. 202420655796.3 filed on April 1, 2024. The content of the aforementioned applications, including any intervening amendments thereto, are incorporated herein by reference.

### BACKGROUND

### TECHNICAL FIELD

The present disclosure relates to the field of air conditioning, and in particular, to an air conditioner.

### DESCRIPTION OF RELATED ART

Air conditioners are commonly used household electrical appliances in people's daily lives, and may be categorized into wall-mounted air conditioners and floor-standing air conditioners. An air conditioner generally includes an indoor unit and an outdoor unit. The indoor unit is mounted on an indoor side, and the outdoor unit is mounted on an outdoor side. A duct-type air conditioner is a type of central air conditioner, in which an indoor unit is generally connected to an outdoor unit. Indoor air passes through a return air duct into the indoor unit, undergoes heat exchange, and then is sent back indoors through a supply air duct, to regulate an indoor temperature.

### SUMMARY

In one aspect, an air conditioner is provided, including an outdoor unit and an indoor unit. The indoor unit is connected to the outdoor unit. The indoor unit includes a housing, a heat exchange assembly, a fan, and an electrical control assembly. The housing includes an air inlet and an air outlet. The heat exchange assembly includes a heat exchanger and a drain pan. The heat exchanger is configured to exchange heat with an airflow flowing therethrough to form a heat-exchange airflow. The drain pan is disposed on one side of the heat exchanger. The drain pan is configured to collect water generated on a surface of the heat exchanger. The fan is configured to drive the airflow to enter the housing via the air inlet to exchange heat with the heat exchanger, and to send out the airflow after heat exchange via the air outlet. The electrical control assembly includes an electrical control box and a circuit board. The circuit board is disposed in the electrical control box. The heat exchange assembly, the fan, and the electrical control box are respectively disposed in the housing. Along an airflow flow direction inside the housing, the heat exchange assembly and the electrical control box are arranged in sequence. The electrical control box includes an electrical control box body and a diversion surface. The diversion surface is disposed on the electrical control box body and is arranged facing the drain pan. The diversion surface is obliquely disposed on the housing.

In another aspect, an air conditioner is provided, including an outdoor unit and an indoor unit. The indoor unit is connected to the outdoor unit. The indoor unit includes a housing, a heat exchange assembly, a fan, and an electrical control assembly. The housing includes an air inlet and an air outlet. The heat exchange assembly includes a heat exchanger and a drain pan. The heat exchanger is configured to exchange heat with an airflow flowing therethrough to form a heat-exchange airflow. The drain pan is disposed on one side of the heat exchanger. The fan is configured such that the airflow is introduced through the air inlet, passes through the heat exchanger, and is then sent out from the air outlet. The electrical control assembly includes an electrical control box and a circuit board. The circuit board is disposed in the electrical control box. The heat exchange assembly, the fan, and the electrical control box are disposed in the housing, and along an airflow flow direction inside the housing, the heat exchange assembly and the electrical control box are arranged in sequence. The housing further includes a second shielding portion and a diversion surface. The second shielding portion is disposed inside the housing and protrudes and extends obliquely from an inner wall of the housing. The second shielding portion is located between the electrical control box and the drain pan. The diversion surface is disposed on a surface of the second shielding portion facing the drain pan. When the housing is mounted vertically, the second shielding portion is located below a drain outlet of the drain pan, and the second shielding portion shields a side edge of the electrical control box adjacent to the drain pan.

### BRIEF DESCRIPTION OF THE DRAWINGS

FIG. 1A is a structural view of an air conditioner according to some embodiments.

FIG. 1B is a block diagram of an air conditioner according to some embodiments.

FIG. 1C is a structural view of a duct-type air conditioner according to some embodiments.

FIG. 2 is a sectional view of the duct-type air conditioner in FIG. 1C.

FIG. 3 is a partial structural view of the duct-type air conditioner in FIG. 1C.

FIG. 4 is an assembly view of a mounting bracket, a fan, and an electrical control assembly in FIG. 3.

FIG. 5 is an exploded view of the fan and the electrical control assembly in FIG. 4.

FIG. 6 is an assembly view of the mounting bracket and the electrical control assembly in FIG. 4.

FIG. 7A is a structural view of a box body in FIG. 4.

FIG. 7B is a structural view of an electrical control box according to some embodiments.

FIG. 8 is a structural view of a fan according to some embodiments.

FIG. 9 is another structural view of a fan according to some embodiments.

FIG. 10 is an assembly view of a motor and a mounting assembly in FIG. 9.

FIG. 11 is a structural view of a first bracket in FIG. 10.

FIG. 12 is a structural view of a second bracket in FIG. 10.

FIG. 13 is a structural view of the motor in FIG. 10.

FIG. 14 is a sectional view of a rotating shaft and a third bracket in FIG. 10.

FIG. 15 is a structural view of another fan according to some embodiments.

FIG. 16 is an assembly view of a motor and a mounting assembly in FIG. 15.

FIG. 17 is a structural view of a fourth bracket in FIG. 16.

FIG. 18 is a structural view of a locking member in FIG. 16.

FIG. 19 is a structural view of the motor in FIG. 16.

FIG. 20 is an assembly view of a second damping portion and a third fitting portion in FIG. 16.

### DESCRIPTION OF THE EMBODIMENTS

Some embodiments of the present disclosure will be described clearly and completely with reference to the accompanying drawings. Obviously, the described embodiments are merely some but not all of embodiments of the present disclosure. All other embodiments obtained by those of ordinary skill in the art based on the embodiments provided in the present disclosure fall within the protection scope of the present disclosure.

Unless otherwise required in the context, throughout the specification and the claims, the term "comprise" and other forms thereof such as the third-person singular form "comprises" and the present participle form "comprising" are construed as an open and inclusive meaning, i.e., mean "including, but not limited to." In the description of the specification, the terms such as "one embodiment," "some embodiments," "exemplary embodiments," "example," "specific example," or "some examples" are intended to indicate that specific features, structures, materials, or characteristics related to the embodiment(s) or example(s) are included in at least one of the embodiments or examples of the present disclosure. Schematic representations of the above terms do not necessarily refer to the same embodiment(s) or example(s). In addition, the specific features, structures, materials, or characteristics may be included in any one or more embodiments or examples in any suitable manner.

In the following, the terms "first", "second", and "third" are used for descriptive purposes only, and are not to be construed as indicating or implying relative importance or implicitly indicating the number of indicated technical features. Thus, features defined by "first", "second", and "third" may explicitly or implicitly include one or more of the features. In the description of the embodiments of the present disclosure, the term "a plurality of" means two or more unless otherwise specified.

In the description of some embodiments, the expressions "coupled," "connected," and derivatives thereof may be used. The term "connected" should be interpreted broadly. For example, "connection" may be a fixed connection, a detachable connection, or an integral formation; or may be a direct connection or an indirect connection through an intermediate medium. The term "coupled" indicates that two or more components are in direct physical or electrical contact. The term "coupled" or "communicatively coupled" may also mean that two or more components are not in direct contact with each other, but still cooperate or interact with each other. The embodiments disclosed herein are not necessarily limited to the content herein.

The phrase "at least one of A, B, and C" has the same meaning as the phrase "at least one of A, B, or C", both including the following combinations of A, B, and C: only A, only B, only C, a combination of A and B, a combination of A and C, a combination of B and C, and a combination of A, B, and C.

The use of the phrase "adapted to" or "configured to" herein means an open and inclusive expression, which does not exclude devices that are adapted to or configured to perform additional tasks or steps.

The term such as "parallel," "perpendicular," or "equal" as used herein includes a stated condition and a condition similar to the stated condition. A range of the similar condition is within an acceptable deviation range, and the acceptable deviation range is determined by those of ordinary skill in the art, considering measurement in question and errors associated with measurement of a particular quantity (i.e., limitations of a measurement system). For example, the term "parallel" includes absolute parallelism and approximate parallelism, and an acceptable range of deviation of the approximate parallelism may be, for example, a deviation within 5°. The term "perpendicular" includes absolute perpendicularity and approximate perpendicularity, and an acceptable range of deviation of the approximate perpendicularity may also be, for example, a deviation within 5°. The term "equal" includes absolute equality and approximate equality, and an acceptable range of deviation of the approximate equality may be, for example, a difference between two equals being less than or equal to 5% of either of the two equals.

Some embodiments of the present disclosure provide an air conditioner.

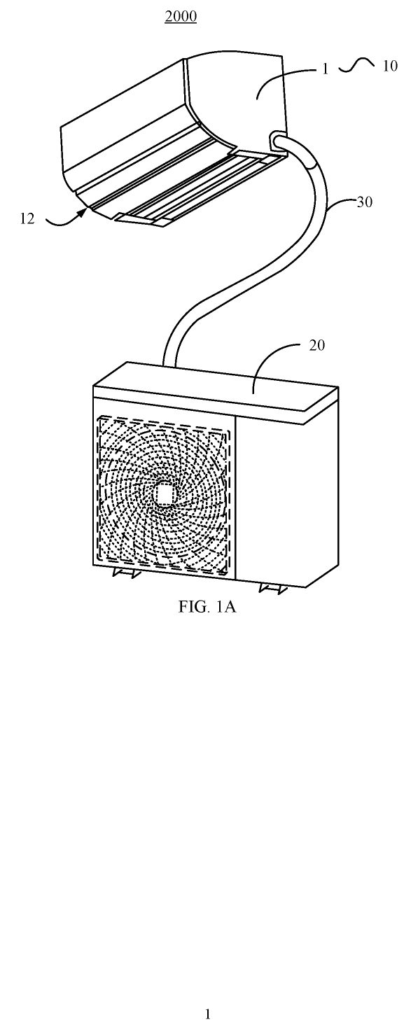

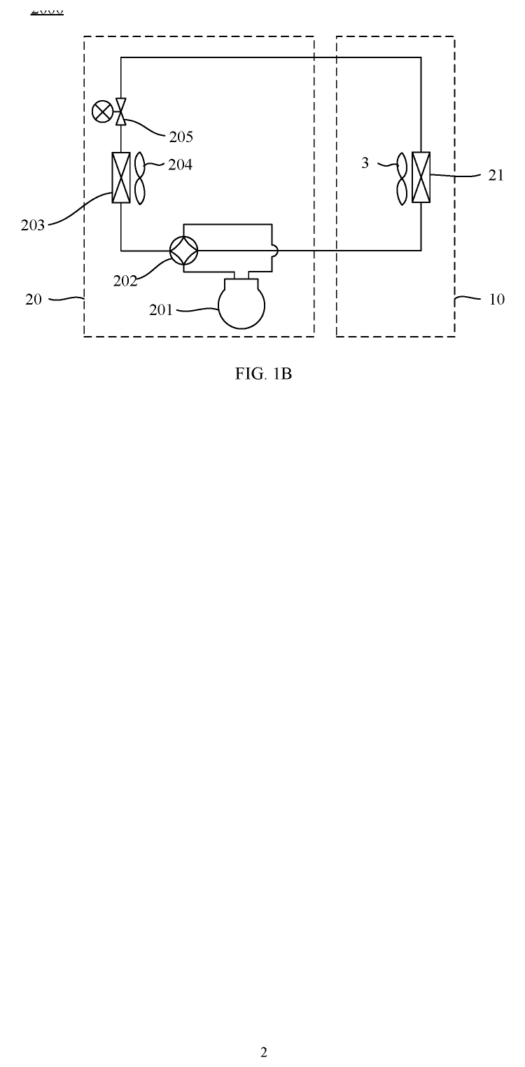

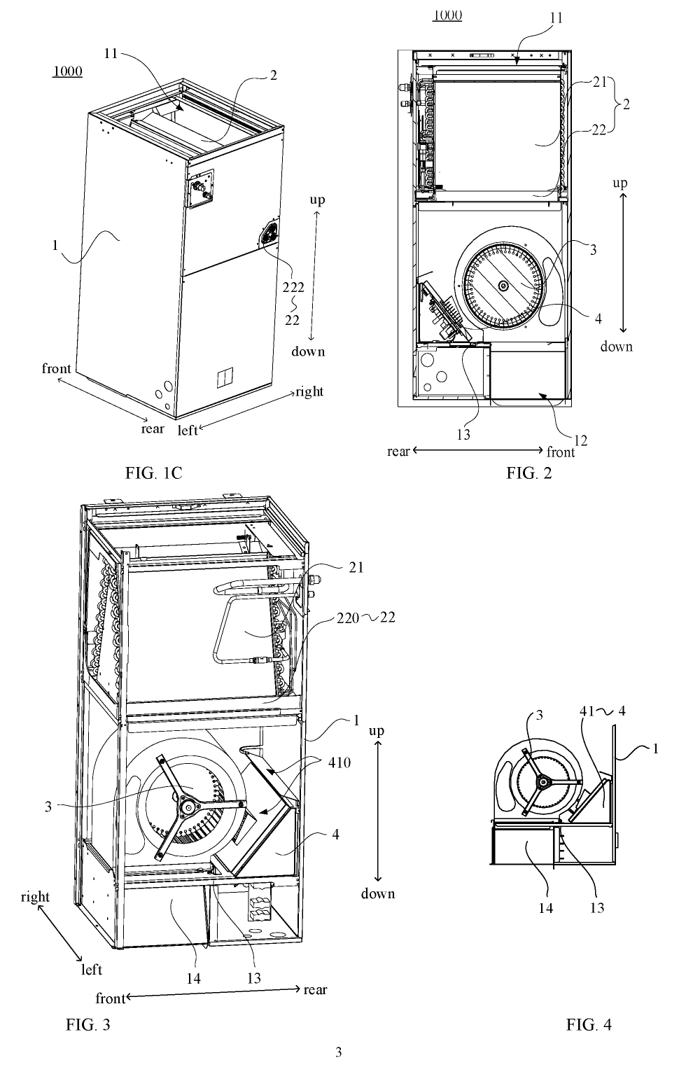

As shown in FIG. 1A and FIG. 1B, an air conditioner 2000 includes an outdoor unit 20.

In some embodiments, the air conditioner 2000 further includes an indoor unit 10. The indoor unit 10 is connected to the outdoor unit 20.

In some embodiments, the air conditioner 2000 further includes a pipeline 30. The indoor unit 10 and the outdoor unit 20 are connected via the pipeline 30 to transfer refrigerant.

In some embodiments, the outdoor unit 20 includes a compressor 201. The compressor 201 is configured to compress the refrigerant so that low-pressure refrigerant is compressed to form high-pressure refrigerant.

In some embodiments, the outdoor unit 20 further includes a first heat exchanger 203 (an outdoor heat exchanger). The first heat exchanger 203 is configured to perform heat exchange between outdoor air and the refrigerant transferred in the first heat exchanger 203. For example, the first heat exchanger 203 operates as a condenser in a cooling mode of the air conditioner 2000, so that the refrigerant compressed by the compressor 201 dissipates heat to outdoor air via the first heat exchanger 203 and condenses. The first heat exchanger 203 operates as an evaporator in a heating mode of the air conditioner 2000, so that depressurized refrigerant absorbs heat from the outdoor air and evaporates via the first heat exchanger 203.

In some embodiments, the first heat exchanger 203 further includes heat exchange fins to increase a contact area between the outdoor air and the refrigerant transferred in the first heat exchanger 203, thereby improving heat exchange efficiency between the outdoor air and the refrigerant.

In some embodiments, the outdoor unit 20 further includes a first fan 204. The first fan 204 is configured to draw the outdoor air into the outdoor unit 20 via an outdoor air inlet of the outdoor unit 20, and to send out the outdoor air after heat exchange with the first heat exchanger 203 via an outdoor air outlet of the outdoor unit 20. The first fan 204 provides power for flow of the outdoor air.

In some embodiments, the indoor unit 10 includes a second heat exchanger 21 (i.e., a heat exchanger). The second heat exchanger 21 is configured to perform heat exchange between indoor air and the refrigerant transferred in the second heat exchanger 21. For example, the second heat exchanger 21 operates as an evaporator in the cooling mode of the air conditioner 2000, so that the refrigerant, after dissipating heat via the first heat exchanger 203, absorbs heat from the indoor air via the second heat exchanger 21 and evaporates. The second heat exchanger 21 operates as a condenser in the heating mode of the air conditioner 2000, so that the refrigerant, after absorbing heat via the first heat exchanger 203, dissipates heat to the indoor air via the second heat exchanger 21 and condenses.

In some embodiments, the second heat exchanger 21 further includes heat exchange fins to increase a contact area between the indoor air and the refrigerant transferred in the second heat exchanger 21, thereby improving heat exchange efficiency between the indoor air and the refrigerant.

As shown in FIG. 1A and FIG. 1B, the indoor unit 10 further includes a second fan 3 (i.e., the fan), and the second fan 3 is configured to draw the indoor air into the indoor unit 10 via an indoor air inlet of the indoor unit 10, and to send out the indoor air after heat exchange with the second heat exchanger 21 via an air outlet 12 of the indoor unit 10. The second fan 3 provides power for flow of the indoor air.

In some embodiments, the compressor 201, the first heat exchanger 203, an expansion valve 205, and the second heat exchanger 21 that are connected in sequence form a refrigerant circuit. The refrigerant circulates in the refrigerant circuit, exchanging heat with air respectively through the first heat exchanger 203 and the second heat exchanger 21, to achieve the cooling mode or the heating mode of the air conditioner 2000.

In some embodiments, the outdoor unit 20 further includes the expansion valve 205. The expansion valve 205 is connected between the first heat exchanger 203 and the second heat exchanger 21. An opening degree of the expansion valve 205 regulates pressure of the refrigerant flowing through the first heat exchanger 203 and the second heat exchanger 21, so as to regulate a flow rate of the refrigerant circulating between the first heat exchanger 203 and the second heat exchanger 21. The flow rate and the pressure of the refrigerant circulating between the first heat exchanger 203 and the second heat exchanger 21 may affect heat exchange performance of the first heat exchanger 203 and the second heat exchanger 21. The expansion valve 205 may be an electronic valve. The opening degree of the expansion valve 205 is adjustable to control the flow rate and the pressure of the refrigerant flowing through the expansion valve 205.

In some embodiments, the outdoor unit 20 further includes a four-way valve 202. The four-way valve 202 is connected within the refrigerant circuit. The four-way valve 202 is configured to switch a flow direction of the refrigerant in the refrigerant circuit, so that the air conditioner 2000 operates in the cooling mode or the heating mode.

A duct-type air conditioner is a type of concealed air conditioner. The duct-type air conditioner addresses the problem of aesthetic caused by the fact that the wall-mounted or floor-standing units exposing to the outside, and also offers longer piping lengths than ordinary household air conditioners, resulting in more flexible mounting, which is an emerging type of air conditioner.

Generally, the duct-type air conditioner includes a housing, a heat exchanger, a fan, an electrical control box, and the like. The electrical control box is configured to control operation of the fan. During use, the duct-type air conditioner may be mounted vertically or horizontally. In the case of being mounted vertically, the fan and the electrical control box are typically mounted below the heat exchanger. During the operation of the duct-type air conditioner, condensate water generated on a surface of the heat exchanger may drip down into a drain pan located below the heat exchanger. However, when the drain pan does not drain smoothly, the water in the drain pan is likely to overflow into the electrical control box below, thereby causing a short circuit in the circuit board inside the electrical control box, resulting in damage to the duct-type air conditioner.

To solve the above problems, some embodiments of the present disclosure provide a duct-type air conditioner 1000. By providing a diversion surface on a side of the electrical control box facing the drain pan, water overflowing from the drain pan is diverted to the outer side of the housing 1. In addition, the electrical control box is further provided therein with components such as a sealing plate, a water blocking portion, and a rubber plug for wiring, to prevent the water from entering the interior of the electrical control box, thereby improving waterproof performance of the electrical control box and operational reliability of the duct-type air conditioner.

Referring to FIG. 1C and FIG. 2, the duct-type air conditioner 1000 includes a housing 1. The housing 1 includes a first chamber. The first chamber is configured for mounting of components such as a heat exchange assembly, a fan, and an electrical control assembly. The housing 1 protects the components inside the first chamber.

In some embodiments, the housing 1 further includes an air inlet 11. In FIG. 1C, the air inlet 11 may be located at the top of the housing 1, and the airflow may enter the housing 1 via the air inlet 11 for heat exchange.

In some embodiments, the housing 1 further includes an air outlet 12. In FIG. 1C, the air outlet 12 may be located at the bottom of the housing 1, and the airflow after heat exchange may flow out via the air outlet 12.

In some embodiments, the air inlet 11 and the air outlet 12 are disposed opposite to each other. For example, the air inlet 11 is disposed at the top of the housing 1, while the air outlet 12 is disposed at the bottom of the housing 1. Alternatively, the air inlet 11 is disposed at the bottom of the housing 1, while the air outlet 12 is disposed at the top of the housing 1.

In some embodiments, referring to FIG. 2, the duct-type air conditioner 1000 further includes a heat exchange assembly 2, and the heat exchange assembly 2 is disposed in the housing 1. The heat exchange assembly 2 is configured to exchange heat with the airflow entering the housing 1, to perform heating or cooling treatment on the airflow.

In some embodiments, the heat exchange assembly 2 includes a heat exchanger 21. The heat exchanger 21 is configured to exchange heat with the airflow flowing therethrough to form a heat-exchange airflow.

Since the heat exchanger 21 may generate condensate water or defrost water during use, the heat exchange assembly 2 further includes a drain pan 22. The drain pan 22 is arranged on one side of (e.g., below) the heat exchanger 21 to collect water generated on a surface of the heat exchanger 21. Herein, the water may include the condensate water and the defrost water as described above.

In some embodiments, referring to FIG. 1C and FIG. 3, the drain pan 22 includes a drain pan body 220 and a drain outlet 222. The drain outlet 222 is in communication with the drain pan body 220 and an exterior of the housing 1. During use, the water generated on the surface of the heat exchanger 21 may flow into the drain pan body 220 and be discharged through the drain outlet 222 and a drain pipe connected to the drain outlet 222.

In some embodiments, to ensure that the water in the drain pan body 220 can be discharged smoothly, the drain pan body 220 is configured to be inclined towards the drain outlet 222, so that the water in the drain pan body 220 flows to the position of the drain outlet 222.

In some embodiments, referring to FIG. 2 and FIG. 3, the duct-type air conditioner 1000 further includes a fan 3. The fan 3 is disposed in the housing 1. For example, the fan 3 and the heat exchange assembly 2 are spaced apart in a height direction of the housing 1, and the fan 3 is disposed below the heat exchange assembly 2. The fan 3 is configured to drive the air to flow, so that the airflow enters the housing 1 via the air inlet 11 to exchange heat with the heat exchanger 21, and the airflow after heat exchange is sent out via the air outlet 12.

In some embodiments, referring to FIG. 3, the duct-type air conditioner 1000 further includes an electrical control assembly 4. The electrical control assembly 4 is disposed in the housing 1. The electrical control assembly 4 is configured to be coupled to an external power supply, so as to supply power to electric devices (such as the fan 3) of the duct-type air conditioner 1000. The electrical control assembly 4 is further configured to control an operating state of the electric devices of the duct-type air conditioner 1000.

In some embodiments, referring to FIG. 4 and FIG. 5, the electrical control assembly 4 includes an electrical control box 41. The electrical control box 41 is fixedly disposed in the housing 1. The electrical control box 41 includes a second chamber configured for mounting of a circuit board 42.

In some embodiments, the electrical control assembly 4 further includes at least one circuit board 42. The circuit board 42 is disposed in the second chamber of the electrical control box 41, so that the circuit board 42 is mounted in the housing 1 by the electrical control box 41. The circuit board 42 is configured to supply power to the electric devices of the duct-type air conditioner 1000 and control the operating state of the electric devices of the duct-type air conditioner 1000.

It is to be noted that the number of the circuit board 42 may be set according to a function of the duct-type air conditioner 1000.

In some embodiments, along an airflow flow direction inside the housing 1, the heat exchange assembly 2 and the electrical control box 41 are arranged in sequence.

For example, referring to FIG. 2, when the housing 1 is in an upright state, the heat exchange assembly 2 is located above the electrical control box 41. In this case, the electrical control box 41 is located below the drain pan body 220. During use, water flowing down from the surface of the heat exchanger 21 may flow into the drain pan body 220, so as to be discharged through the drain outlet 222 of the drain pan 22 and the drain pipe.

However, if the drain pan 22 fails to drain smoothly, a water within the drain pan body 220 may has a water level that continues to rise and eventually overflows from the drain pan body 220. In this case, the water overflowing from the drain pan body 220 may flow towards the electrical control box 41 located below the drain pan body 220, thereby affecting reliability of the electrical control box 41.

In some embodiments, to improve waterproof performance of the electrical control box 41, referring to FIG. 3, the electrical control box 41 includes an electrical control box body and a diversion surface 410. The diversion surface 410 is configured to divert the water overflowing from the drain pan 22 when the housing 1 is in the upright state.

For example, the diversion surface 410 is disposed on a side of the electrical control box body facing the drain pan 22. The diversion surface 410 is disposed obliquely in the housing 1 to facilitate drainage of the water.

In some embodiments of the present disclosure, the electrical control box 41 is provided with the diversion surface 410 facing the drain pan 22, and the diversion surface 410 is disposed obliquely. In this way, when the housing 1 is in the upright state, the duct-type air conditioner 1000 can divert, by the diversion surface 410, the water overflowing from the drain pan 22.

Guided by the diversion surface 410, the water overflowing from the drain pan 22 can flow downwards quickly and smoothly along the obliquely arranged diversion surface 410. This reduces an impact on the circuit board 42 caused by water ingress into the electrical control box 41, thereby helping to improve the waterproof performance of the electrical control box 41 and operational reliability of the duct-type air conditioner 1000.

In some embodiments, referring to FIG. 4 and FIG. 5, the electrical control box body includes a box body 411. The box body 411 is disposed in the housing 1. The box body 411 defines the second chamber configured for mounting of the circuit board 42. The circuit board 42 is disposed in the box body 411, so as to be assembled into the housing 1 through the box body 411, thereby achieving fixed mounting between the electrical control box and the housing 1.

In some embodiments, the electrical control box body further includes a cover 412. The cover 412 is connected to the box body 411 to close at least part of the second chamber. For example, an opening is formed on a side of the box body 411 adjacent to the cover, and the cover 412 is disposed at the opening of the box body 411.

In some embodiments, the cover 412 is detachably connected to the box body 411. In this way, when the cover 412 is detached from the box body 411, the circuit board 42 can be exposed, thereby facilitating maintenance of the circuit board 42.

In some embodiments, the diversion surface 410 of the electrical control box 41 satisfies at least one of the following: the diversion surface 410 is disposed on the box body 411, or the diversion surface 410 is disposed on the cover 412.

In some embodiments, when the diversion surface 410 is disposed on the box body 411, the diversion surface 410 is disposed on an obliquely arranged outer surface of the box body 411. When the housing 1 is in the upright state, the diversion surface 410 is located on a side of the drain pan 22 away from the heat exchanger 21, and is spaced apart from the drain pan 22.

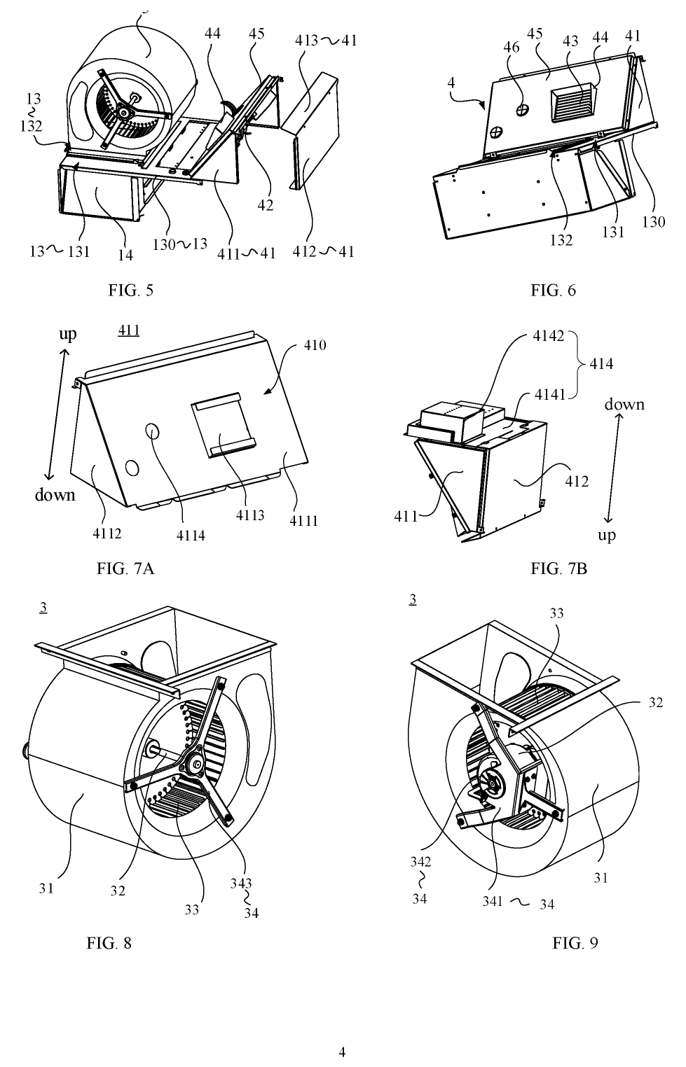

Referring to FIG. 2, FIG. 3, and FIG. 7A, an outer surface on a side of the box body 411 facing the drain pan 22 and the fan 3 is disposed obliquely to form the diversion surface 410. In a direction away from the drain pan 22, the diversion surface 410 extends obliquely towards a direction away from an inner wall of the housing 1. For example, a first end of the diversion surface 410 is adjacent to the inner wall of the housing 1 and the drain pan 22, and a second end of the diversion surface 410 is away from the inner wall of the housing 1 and the drain pan 22.

In this way, by disposing the outer surface of the box body 411 obliquely to form the diversion surface 410, it is easy to divert, by using the oblique outer surface of the box body 411, the water overflowing from the drain pan 22.

In some embodiments, referring to FIG. 7A, the box body 411 includes a first plate 4111 (a mounting plate). The diversion surface 410 is disposed on an outer surface of the first plate 4111, and the circuit board 42 is disposed on an inner surface of the first plate 4111.

In some embodiments, the box body 411 further includes two second plates 4112 (curved plates). The two second plates 4112 are respectively disposed on two sides of the first plate 4111, and either of the two second plates 4112 extends towards a direction away from the drain pan 22. For example, a plane in which the first plate 4111 is located may be parallel to a cross section of the fan 3. Herein, the cross section refers to a plane perpendicular to the rotating shaft of the fan 3.

It can be understood that at least one of the first plate 4111 or the second plate 4112 is disposed in the housing 1, so that the box body 411 is mounted in the housing 1.

By disposing the second plates 4112 respectively on the two sides of the first plate 4111, after the circuit board 42 is fixed to the first plate 4111, the second plates 4112 on the two sides can protect the circuit board 42.

In some embodiments, the cover 412 may be connected between the two second plates 4112. The cover 412 cooperates with the two second plates 4112, so that a relatively enclosed second chamber is formed among the box body 411, the cover 412, and the housing 1, for the mounting of the circuit board 42.

In some embodiments, referring to FIG. 3 and FIG. 7B, the electrical control box 41 further includes a maintenance cover 414. The maintenance cover 414 is disposed on a side (e.g., a lower side) of the box body 411 away from the heat exchange assembly 2. The maintenance cover 414 is detachably connected to the box body 411, so as to facilitate detachment of the maintenance cover 414 to perform inspection and maintenance on the circuit board 42 in the electrical control box 41.

It can be understood that the maintenance cover 414, the box body 411, and the cover 412 cooperate with each other, which can further improve sealing performance of the electrical control box 41.

In some embodiments, referring to FIG. 7B, the maintenance cover 414 includes a first sub-cover 4141. The first sub-cover 4141 includes a maintenance opening. The maintenance cover 414 further includes a second sub-cover 4142. The second sub-cover 4142 is detachably disposed at the maintenance opening.

In this way, the maintenance cover 414 is configured as a split structure, and easily damaged devices are disposed at the circuit board 42 corresponding to the maintenance opening of the first sub-cover 4141. When the maintenance is required, the maintenance can be performed only by removing the second sub-cover 4142, which can further facilitate later inspection and maintenance.

In addition, it should be noted that the second sub-cover 4142 may protrude from an outer surface of the first sub-cover 4141. That is, when the duct-type air conditioner 1000 is mounted vertically, the second sub-cover 4142 extends downwards along the outer surface of the first sub-cover 4141. In this way, when the water in the drain pan 22 overflows, the second sub-cover 4142 can guide the water flowing onto the surface of the electrical control box 41, downwards, which is beneficial to quickly draining the water out of the housing 1 and further improving the waterproof performance of the electrical control assembly 4.

In other embodiments, when the diversion surface 410 is disposed on the cover 412, the diversion surface 410 is disposed at an end of the cover 412 adjacent to the drain pan 22.

Referring to FIG. 3 and FIG. 5, the electrical control box 41 further includes a first shielding portion 413 (a first shielding plate). The first shielding portion 413 is disposed on a side of the cover adjacent to the drain pan, and is disposed obliquely in the housing 1. For example, a first end of the first shielding portion 413 is disposed at an end (i.e., an upper end) of the cover 412 adjacent to the drain pan 22, and a second end of the first shielding portion 413 extends obliquely away from the corresponding inner wall of the housing 1 and towards a direction approaching the drain pan 22. A surface of the first shielding portion 413 facing the drain pan 22 forms the diversion surface 410.

When the housing 1 is in the upright state, the first shielding portion 413 is located between the box body 411 and the drain pan 22. For example, the first shielding portion 413 is located at the bottom of the drain outlet 222 of the drain pan 22 and covers a side edge (e.g., an upper edge) of the box body 411 adjacent to the drain pan 22.

In this way, the water overflowing from the drain pan 22 can fall onto the first shielding portion 413, and be guided by the first shielding portion 413 to flow towards the inner wall of the housing 1, so as to achieve quick drainage, thereby preventing the water from flowing into the box body 411, which is conducive to improving waterproof performance of the electrical control box.

It should be noted that, in some embodiments, the cover 412 abuts against an inner wall (e.g., a rear wall) of the housing 1. In this case, the cover contacts the corresponding inner wall of the housing, and there is no gap therebetween. The water overflowing from the drain pan 22, after falling onto the first shielding portion 413, may be discharged via gaps between two ends (e.g., left and right ends as shown in FIG. 3) of the first shielding portion 413 and corresponding inner walls of the housing.

Certainly, in some other embodiments, the cover 412 and the inner wall of the housing 1 are spaced apart by a predetermined distance. In this case, the water overflowing from the drain pan 22, after falling onto the first shielding portion 413, may be discharged via a gap between the cover 412 and the inner wall of the housing 1.

In still other embodiments, referring to FIG. 3, each of the box body 411 and the cover 412 is provided with the diversion surface 410. In this way, efficiency of water drainage is effectively improved, which is more conducive to improving a waterproof effect of the electrical control box.

It can be understood that, since the circuit board 42 may generate heat during use when powered on, heat dissipation treatment is required for the circuit board 42.

In some embodiments, referring to FIG. 7A, the box body 411 further includes a heat dissipation opening 4113. The heat dissipation opening 4113 is disposed in the first plate 4111. For example, the heat dissipation opening 4113 may be located at the diversion surface 410.

Referring to FIG. 6, the electrical control assembly 4 further includes a heat dissipation portion 43. The heat dissipation portion 43 is disposed in the electrical control box 41. The heat dissipation portion 43 is located at the heat dissipation opening 4113. The heat dissipation portion 43 is inserted into the heat dissipation opening 4113 to close the heat dissipation opening 4113, and the heat dissipation portion 43 is in thermal conductive connection with the circuit board 42 to dissipate heat from the circuit board 42. The heat dissipation portion 43 may be made of a material having thermal conductivity (such as aluminum or copper).

In summary, by providing the heat dissipation opening 4113 in the first plate 4111 and disposing the heat dissipation portion 43, which is in thermal conductive connection with the circuit board 42, at the heat dissipation opening 4113, the heat dissipation portion 43 can be utilized to dissipate heat from the circuit board 42, thereby helping to ensure operational reliability of the circuit board.

In some embodiments, the heat dissipation portion 43 is sealingly connected to the heat dissipation opening 4113, so as to prevent the water overflowing from the drain pan 22 from entering the electrical control box 41 via a gap between the heat dissipation opening 4113 and the heat dissipation portion 43. For example, the gap between the heat dissipation opening 4113 and the heat dissipation portion 43 can be sealed by means of sealant or by providing a sealing ring, or the like. It should be noted that the sealing referred to herein is relative sealing.

In some embodiments, to prevent the water overflowing from the drain pan 22 from flowing to the heat dissipation portion 43, referring to FIG. 5 and FIG. 6, the electrical control assembly 4 further includes a water blocking portion 44. The water blocking portion 44 is disposed on an outer side of the heat dissipation portion 43 and is configured to prevent the water from flowing to the heat dissipation portion 43. For example, the water blocking portion 44 is disposed on a side of the first plate 4111 facing the drain pan 22, and protrudes from the outer surface of the first plate 4111.

When the housing 1 is vertically arranged, the water blocking portion 44 may be located above the heat dissipation portion 43 to shield the heat dissipation portion 43. In this way, the water overflowing from the drain pan 22 when flowing on the diversion surface 410 of the box body 411 can be blocked by the water blocking portion 44, thereby bypassing the heat dissipation portion 43.

In some embodiments, the water blocking portion 44 has an annular structure, and the water blocking portion 44 is arranged around a periphery of the heat dissipation opening 4113.

In some other embodiments, the water blocking portion 44 includes a first sub water blocking portion, a second sub water blocking portion, and a third sub water blocking portion. Ends of the first sub water blocking portion and the second sub water blocking portion that are adjacent to each other are connected to each other, ends of the second sub water blocking portion and the third sub water blocking portion that are adjacent to each other are connected to each other; the first sub water blocking portion and the third sub water blocking portion are spaced apart to form an opening. The opening is disposed away from the drain pan.

For example, the water blocking portion 44 may have a U-shaped cross-section, the water blocking portion 44 is arranged around the periphery of the heat dissipation opening 4113, and a side of the water blocking portion 44 away from the drain pan 22 is provided with the above opening.

In some embodiments, referring to FIG. 6 and FIG. 7A, the box body 411 further includes a first hole 4114 (a wiring hole). The first hole 4114 extends through the first plate 4111 along a thickness direction. A cable coupled to the circuit board 42 in the box body 411 extends out of the electrical control box 41 via the first hole 4114, so as to be coupled to the electrical devices of the duct-type air conditioner 1000.

In some embodiments, the electrical control assembly 4 further includes a wiring portion 46 (e.g., a rubber plug for wiring). The wiring portion 46 is disposed at the first hole 4114. In this case, the cable coupled to the circuit board 42 extends out of the electrical control box 41 via the wiring portion 46. The wiring portion 46 can seal a gap between the first hole 4114 and the cable, so as to further enhance the waterproof performance of the electrical control assembly 4.

In some embodiments, the electrical control box 41 further includes a sealing plate 45. The sealing plate 45 covers a side of the first plate 4111 adjacent to the drain pan 22., and an inclination direction of the sealing plate 45 is the same as that of the diversion surface.

In some embodiments, the heat dissipation portion 43 extends through the sealing plate 45, and at least part of the water blocking portion 44 is located outside the sealing plate 45. The heat dissipation portion 43 is sealingly connected to the heat dissipation opening 4113 by the sealing plate 45, thereby sealing a junction between the heat dissipation portion 43 and the heat dissipation opening 4113 by using the sealing plate 45 and the water blocking portion 44.

The arrangement of the sealing plate 45 can cover the diversion surface 410 of the box body 411, so that the first hole 4114 of the box body 411 as well as a connection gap between the heat dissipation opening 4113 and the heat dissipation portion 43 can be covered and sealed by the sealing plate 45, thereby helping to improve the waterproof performance of the electrical control assembly 4.

In some embodiments, referring to FIG. 5 and FIG. 6, the duct-type air conditioner 1000 further includes a mounting bracket 13 (a mounting support frame). The mounting bracket 13 is fixedly disposed in the housing 1 and is configured to support the fan 3 and the electrical control assembly 4. The fan 3 and the electrical control assembly 4 are disposed on the mounting bracket 13.

In some embodiments, the mounting bracket 13 includes a mounting bracket body 130 and a mounting surface 131. The mounting surface 131 is located on a side of the mounting bracket body 130 facing the heat exchange assembly 2.

In some embodiments, the electrical control assembly 4 and the fan 3 are disposed on the same side of the mounting bracket 13. For example, the electrical control assembly 4 and the fan 3 are disposed on the mounting surface 131. In this case, the electrical control assembly 4 and the fan 3 are disposed between the mounting bracket 13 and the heat exchange assembly 2.

It can be understood that the electrical control box 41 of the electrical control assembly 4 may cooperate with the mounting surface 131 to form the second chamber.

In some embodiments, to satisfy a requirement of the fan 3 for driving the airflow to flow, the mounting bracket 13 further includes a vent 132 (a ventilation connection port). The vent 132 is disposed on the mounting surface 131. The fan 3 is disposed on the mounting surface 131 and is in communication with the vent 132. An outlet of the fan 3 and the vent 132 are in communication with the air outlet 12.

In this way, after the fan 3 is started, the airflow outside the housing 1 enters the housing 1 via the air inlet 11 to exchange heat with the heat exchanger 21, then enters the fan 3, is outputted from the outlet of the fan 3 and the vent 132, and is transferred to the outside of the housing 1 via the air outlet 12.

In some embodiments, to improve heat dissipation efficiency of the heat dissipation portion 43, the heat dissipation portion 43 of the electrical control assembly 4 may be arranged adjacent to the fan 3. For example, the heat dissipation opening 4113 is disposed on a side of the electrical control box 41 facing the fan 3, and the heat dissipation portion 43 is disposed at the heat dissipation opening 4113.

In this way, after the fan 3 is started, the airflow after heat exchange via the heat exchanger 21 is driven by the fan 3 to flow towards a direction where the fan 3 is located. During the flow of the airflow, one part of the airflow enters an inlet of the fan 3, while another part of the airflow flows along the outer surface of the first plate 4111 of the electrical control box 41, so as to carry away heat that is dissipated by the circuit board 42 and absorbed by the heat dissipation portion 43, thereby improving the heat dissipation efficiency of the heat dissipation portion 43.

In some embodiments, referring to FIG. 3 to FIG. 5, the duct-type air conditioner 1000 further includes a diversion cover 14. The diversion cover 14 is disposed at the vent 132 to guide the airflow outputted from the fan 3.

For example, the diversion cover 14 is located between the vent 132 and the air outlet 12, which facilitates the diversion cover 14 to guide the airflow towards the air outlet 12.

In some embodiments, a sectional area of the diversion cover 14 gradually increases along an air outlet direction. This facilitates increasing an air outlet coverage area of the air outlet 12, so as to increase an air output volume of the duct-type air conditioner 1000.

In some other embodiments, the duct-type air conditioner 1000 further includes a second shielding portion (second shielding plate). The second shielding portion is disposed on an inner wall of the housing 1 and protrudes and extends obliquely from the inner wall of the housing 1. The second shielding portion is configured to perform water blocking treatment on the electrical control box 41, so as to enhance the waterproof performance of the electrical control box 41.

Herein, it should be noted that the second shielding portion may adopt a structure similar to that of the first shielding portion as described above, which is not repeatedly described in detail herein again.

In some embodiments, the second shielding portion is located between the electrical control box 41 and the drain pan 22, and a surface of the second shielding portion facing the drain pan 22 forms the diversion surface 410.

When the housing 1 is vertically arranged, the second shielding portion is located below the drain outlet 222 of the drain pan 22, and the second shielding portion shields an upper edge of the box body 411. In this way, when the drain pan 22 overflows, the water overflowing from the drain pan 22 may be blocked by the second shielding portion and be diverted towards the inner wall of the housing 1, so as to flow down along the inner wall of the housing 1. Therefore, the waterproof performance of the electrical control box 41 is improved.

A configuration of the fan 3 in some embodiments of the present disclosure is introduced below.

In some embodiments, as shown in FIG. 8, the fan 3 includes a volute 31. A third chamber is formed inside the volute 31 to accommodate relevant components (e.g., the components such as an impeller and a motor) of the fan 3.

In some embodiments, referring to FIG. 9, the fan 3 further includes an impeller 33. The impeller 33 is rotatably disposed in the third chamber of the volute 31.

In some embodiments, the fan 3 further includes a motor 32. The motor 32 is fixedly disposed in the volute. The motor 32 is connected to the impeller 33. The motor 32 is configured to drive the impeller 33 to rotate in the volute 31.

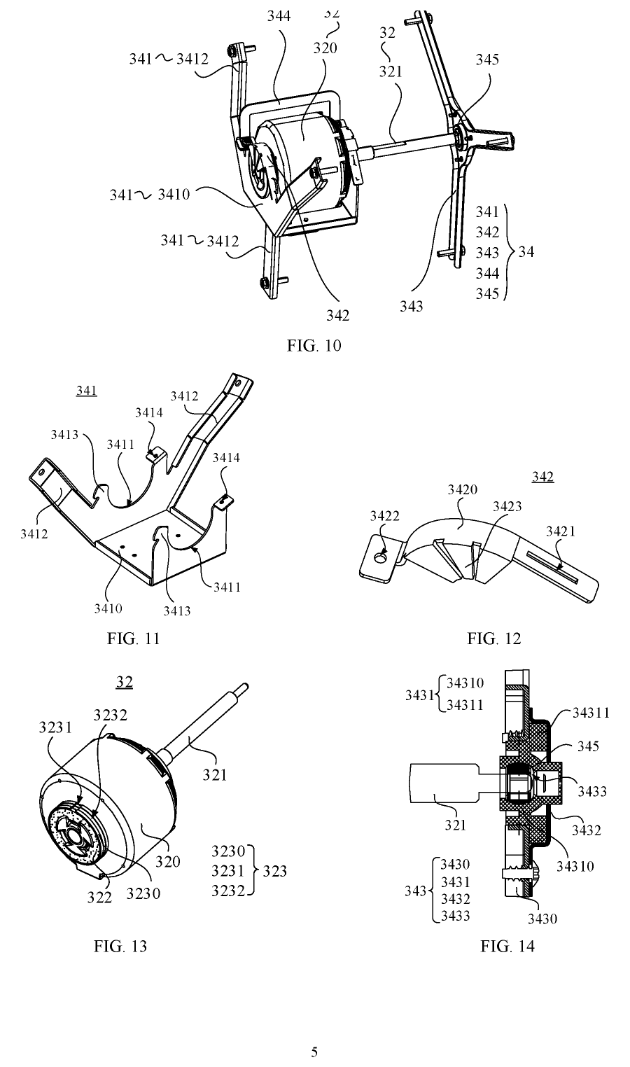

In some embodiments, referring to FIG. 10, the motor 32 includes a motor body 320 and a rotating shaft 321. The motor body 320 is fixedly connected to the rotating shaft 321 to drive the rotating shaft 321 to rotate. The rotating shaft 321 passes through the impeller 33 to drive the impeller 33 to rotate in the volute 31.

During use, the duct-type air conditioner 1000 may be mounted vertically or horizontally. In different mounting states, a mounting angle and a relative position of the fan 3 in the housing 1 may also vary. Therefore, to adapt to the different mounting states of the duct-type air conditioner 1000, there is a need to improve assembling precision and structural stability between the motor 32 of the fan 3 and the volute 31 and between the impeller 33 and the volute 31, so as to enhance operational reliability of the fan 3. Furthermore, during transportation or handling of the duct-type air conditioner 1000, vibration caused by a collision may also affect the operational reliability of the fan 3.

In some embodiments, referring to FIG. 9 and FIG. 10, the fan 3 further includes a mounting assembly 34. In this case, the motor 32 and the impeller 33 are respectively fixed to the volute 31 by the mounting assembly 34, so as to enhance structural stability of the fan 3.

In some embodiments, referring to FIG. 9, the mounting assembly 34 includes a first bracket 341 (a support bracket). The first bracket 341 is disposed on one side of the volute 31 and is fixedly connected to the volute 31. The first bracket 341 is configured to support the motor body 320.

In some embodiments, the mounting assembly 34 further includes a second bracket 342 (a fixing bracket). The second bracket 342 is connected to the first bracket 341 to further fix the motor body 320.

The motor body 320 is disposed between the first bracket 341 and the second bracket 342. In this way, the first bracket 341 and the second bracket 342 can fix the motor body 320 to the one side of the volute 31.

In some embodiments, the mounting assembly 34 further includes a third bracket 343 (an auxiliary bracket). The third bracket 343 is disposed on another side of the volute 31 opposite to the one side. The third bracket 343 is disposed opposite to the first bracket 341. The third bracket 343 is configured to support a free end of the rotating shaft 321. The free end of the rotating shaft 321 is rotatably connected to the third bracket 343.

During the assembling of the fan 3, a first end of the motor body 320 is fixed between the first bracket 341 and the second bracket 342, and a second end of the motor body 320 is connected to the rotating shaft 321. The free end of the rotating shaft 321 passes through the impeller 33, and is then connected to the third bracket 343.

In this way, after the assembling of the fan 3 is completed, the motor body 320 located on one side of the impeller 33 is securely fixed to the first bracket 341, while the free end of the rotating shaft 321 located on another side of the impeller 33 is supported by the third bracket 343. Therefore, during transportation and handling of the duct-type air conditioner 1000 or when the mounting state is changed, the motor 32 and the impeller 33 can be supported and fixed by the mounting assembly 34, thereby improving structural stability of the fan 3.

In summary, by mounting the motor 32 to the volute 31 with the assistance of the mounting assembly 34, the motor 32 can be reliably supported on two sides of the impeller 33, so as to reduce occurrence of deviation of the motor 32, thereby reducing changes in a mounting position of the impeller 33, preventing surging or an inaccurate airflow volume of the fan 3, and improving the operational reliability of the duct-type air conditioner 1000.

In some embodiments, referring to FIG. 11, the first bracket 341 includes a first bracket body 3410 and a bracing portion 3411 (a bracing groove). The bracing portion 3411 is disposed on the first bracket body 3410 and is configured to bear the motor body 320. The motor body 320 is located in the bracing portion 3411. For example, the bracing portion 3411 is a bracing groove. The second bracket 342 is disposed on one side of the first bracket 341 and is configured to press against the motor 32 to prevent the motor 32 from detaching from the bracing portion 3411.

It can be understood that the arrangement of the bracing portion 3411 facilitates positioning of the motor 32, so as to achieve pre-assembly of the motor 32. During assembly, the motor body 320 may be first placed into the bracing portion 3411, and then the second bracket 342 is assembled to the first bracket 341, thereby fixedly mounting the motor 32 onto the first bracket 341 by using the second bracket 342.

In some embodiments, referring to FIG. 11, to achieve a fixed connection between the first bracket 341 and the volute 31, the first bracket 341 further includes a plurality of connecting portions 3412. The plurality of connecting portions 3412 are distributed around the bracing portion 3411. A first end of any one of the plurality of connecting portions 3412 is connected to the first bracket body 3410, and a second end of the any one connecting portion 3412 extends outwards to be connected to the volute 31.

For example, the second end of the any one of the connecting portions 3412 is disposed facing the exterior of the volute 31 and extends radially along an end face on the one side of the volute 31.

In some embodiments, the connecting portion 3412 is detachably mounted on the volute 31.

It should be noted that the connecting portion 3412 and the first bracket body 3410 may have an integral structure. This facilitates the mounting, thereby improving assembling efficiency of the fan 3.

Certainly, the connecting portion 3412 may alternatively have an independent structure. One end of the connecting portion 3412 is mounted on the first bracket body 3410 by fixed connection, and a free end of the connecting portion 3412 may be fixedly connected to the volute 31 through a locking member such as a screw. In this way, when the connecting portion 3412 is damaged, it is easy to detach and replace the connecting portion 3412, thereby reducing maintenance costs.

In some embodiments, referring to FIG. 11 and FIG. 12, in order to securely assemble the second bracket 342 to the first bracket 341, the first bracket 341 further includes first engaging portions 3413 (insertion tongues). The first engaging portions 3413 are disposed on two sides of the first bracket body 3410 respectively and located at a first end of the bracing portion 3411.

The second bracket 342 includes a second bracket body 3420 and a first fitting portion 3421 (an insertion hole). The first fitting portion 3421 is disposed at a first end of the second bracket body 3420. The first engaging portion 3413 is inserted into the first fitting portion 3421 to connect a first end of the second bracket 342 to a first end of the first bracket 341.

It can be understood that the cooperation between the first engaging portion 3413 and the first fitting portion 3421 can reduce the number of screws used, thereby improving assembling efficiency.

In some embodiments, the first bracket 341 further includes a second hole 3414 (a screw hole). The second hole 3414 is disposed at a second end of the first bracket body 3410. The second bracket 342 further includes a third hole 3422 (a connecting through hole). Third hole 3422 is disposed at a second end of the second bracket body 3420.

It can be understood that a screw may pass through the third hole 3422 and be threadedly connected into the second hole 3414.

During fixed mounting of the motor body 320 onto the first bracket 341 by the second bracket 342, the first end of the second bracket 342 is first quickly inserted into and fitted into the first engaging portion 3413 via the first fitting portion 3421. Then, the second end of the second bracket 342 is pressed against one side of the motor 32, and the screw is threaded through the third hole 3422 and threadedly connected into the second hole 3414, so that the assembling of the second bracket 342 and the first bracket 341 is completed.

In some embodiments, the first engaging portion 3413 and the second hole 3414 are respectively disposed on two sides of the bracing portion 3411, and second brackets 342 are respectively disposed on the two sides of the bracing portion 3411.

In some embodiments, the first bracket 341 may be formed by processing a sheet metal part. This helps to ensure structural strength of the first bracket 341 and also helps to improve manufacturing efficiency.

In some embodiments, bracing portions 3411 may be respectively formed on two sides of the first bracket body 341. In this case, the second brackets 342 are respectively connected to the two sides of the first bracket 341. In this way, mounting reliability of the motor body 320 and the volute 31 can be improved.

In some embodiments, to improve overall structural strength of the first bracket 341, referring to FIG. 10, the mounting assembly 34 further includes a first reinforcing member 344 (a reinforcing member). The first reinforcing member 344 may be connected to the two sides of the first bracket 341, for example, between the two bracing portions 3411. The first reinforcing member 344 extends along a length direction (e.g., an axial direction) of the motor body 320 and spans across the motor body 320 to connect two side portions of the first bracket 341, thereby improving structural strength of the first bracket 341.

In some embodiments, referring to FIG. 13, the motor 32 further includes a first damping portion 322. The first damping portion 322 is disposed on each of two end portions of the motor body 320. A side of the first damping portion 322 away from the motor body 320 is clamped between the first bracket 341 and the second bracket 342.

For example, one part of one first damping portion 322 is located in the bracing portion 3411, and another part of the first damping portion 322 is located in the second bracket 342. In this way, by disposing the first damping portions 322 respectively on the two end portions of the motor body 320, vibration generated during the operation of the motor 32 can be absorbed by using the first damping portions 322, thereby reducing noise generated by the motor 32 during operation.

In some embodiments, the first damping portion 322 may be a flexible member such as a damping sleeve or a damping block.

In some embodiments, referring to FIG. 11 to FIG. 13, the motor 32 further includes an engaging ring 323. The engaging ring 323 is sleeved on the outside of the first damping portion 322. In use, the engaging ring 323 is clamped between the first bracket 341 and the second bracket 342, so as to fix the first damping portion 322 to an end portion of the motor body 320, thereby improving operational reliability of the first damping portion 322.

In some embodiments, referring to FIG. 13, the engaging ring 323 includes an engaging ring body 3230 and a third notch portion 3231. The third notch portion 3231 is configured to reserve a compression gap for two end portions of the third notch portion 3231 of the engaging ring 323 after the engaging ring 323 is clamped between the first bracket 341 and the second bracket 342, so that a distance between the two end portions of the engaging ring 323 is reduced. This can improve firmness of the mounting of the motor body 320 between the first bracket 341 and the second bracket 342.

For example, the engaging ring 323 is made of a hard material (such as metal).

After the first damping portion 322 is assembled onto the motor 32, the engaging ring 323 is sleeved on the outside of the first damping portion 322. In this way, the first damping portion 322 can be protected from the outside of the first damping portion 322. When the second bracket 342 presses against the engaging ring 323, the third notch portion 3231 of the engaging ring 323 enables the engaging ring 323 to reduce in size (e.g., a circumference) by using the third notch portion 3231, so that the first damping portion 322 is securely fixed to the motor 32.

In some embodiments, the engaging ring 323 further includes a third limiting portion 3232. The third limiting portion 3232 is disposed on an outer periphery of the engaging ring body 3230. The arrangement of the third limiting portion 3232 can have a limiting effect on the motor body 320. In this way, after the motor body 320 is mounted into the bracing portion 3411, the engaging ring 323 can be fitted into the first bracket 341 by the third limiting portion 3232, such that a portion of the first bracket body 3410 provided with the bracing portion 3411 is engaged into the third limiting portion 3232, thereby improving firmness of mounting of the motor body 320.

In some embodiments, referring to FIG. 10 and FIG. 12, the second bracket 342 further includes a second limiting portion 3423 (a shielding portion). The second limiting portion 3423 is disposed on one side of the second bracket body 3420. The second limiting portion 3423 is configured to cover an outer side of the first damping portion 322, so as to restrict the first damping portion 322 from separating from an end portion of the motor 32.

Referring to FIG. 10, after the second bracket 342 is assembled to the first bracket 341, the second limiting portion 3423 is located on an outer side of the first damping portion 322 and extends towards the first bracket 341. In this case, the first damping portion 322 is located between the second limiting portion 3423 and an end face of the motor body 320.

It can be understood that, during use, the rotating shaft 321 of the motor 32 drives the impeller 33 to rotate, during which the motor body 320 may be caused to generate vibration. If the vibration is transferred to the first damping portion 322, it may cause deformation or displacement of the first damping portion 322. By disposing the second limiting portion 3423 on the second bracket 342, the outer side of the first damping portion 322 may be shielded and limited, which may ensure that the first damping portion 322 can be stably mounted at the end portion of the motor 32 during use, thereby improving operational reliability of the motor.

In some embodiments, to restrict rotation of the motor 32 relative to the first damping portion 322, the first damping portion 322 further includes a first damping portion body. The first damping portion 322 further includes a positioning portion disposed on the first damping portion body. The positioning portion is disposed on an inner circumferential surface of the first damping portion body (a side surface adjacent to a central axis of the motor body 320). The motor 32 further includes a positioning fitting portion. The positioning fitting portion is disposed on a periphery of a side of the motor body 320 connected to the first damping portion 322. The positioning portion is connected to the positioning fitting portion to restrict rotation of the motor 32 relative to the first damping portion 322.

For example, the positioning portion has a recessed structure or a raised structure, and correspondingly, the positioning fitting portion may have a raised structure or a recessed structure.

In some other embodiments, referring to FIG. 14, to ensure smooth rotation of the rotating shaft 321 relative to the third bracket 343, the mounting assembly 34 further includes a bearing 345. The bearing 345 is disposed on the third bracket 343, and the free end of the rotating shaft 321 is disposed on the bearing 345, so as to achieve a rotatable connection between the motor and the third bracket 343 by the bearing 345.

Referring to FIG. 14, the third bracket 343 includes a third bracket body 3430. The third bracket 343 further includes a fourth hole 3433 (a mounting hole) disposed in the third bracket body 3430. The fourth hole 3433 is disposed on a side of the third bracket body 3430 adjacent to the rotating shaft 321. The bearing 345 is disposed in the fourth hole 3433, and the free end of the rotating shaft 321 of the motor 32 is inserted into the bearing 345.

In this way, by disposing the bearing 345 on the third bracket 343, the rotating shaft 321 can be supported by the third bracket 343, and the rotating shaft 321 can rotate smoothly.

In some embodiments, referring to FIG. 14, the third bracket 343 further includes a third damping portion 3431. The third damping portion 3431 is disposed at the fourth hole 3433. In this way, the bearing 345 can be mounted in the fourth hole 3433 of the third bracket 343 by the third damping portion 3431, and the third damping portion 3431 can provide support and damping for the bearing 345.

The third damping portion 3431 includes a mounting groove, and the bearing 345 is disposed in the mounting groove. The third damping portion 3431 further includes a ventilation hole. The ventilation hole is in communication with the mounting groove.

It can be understood that when the rotating shaft 321 of the motor 32 rotates at a high speed, gas in the mounting groove may experience pressure fluctuations, thereby producing abnormal noise, and by providing the ventilation hole, air pressure in the mounting groove can be balanced, thereby reducing occurrence of abnormal noise.

In some embodiments, referring to FIG. 14, the third damping portion 3431 further includes a third damping portion body 34310. The third damping portion 3431 further includes a third positioning portion 34311 disposed on the third damping portion body 34310. The mounting groove and the ventilation hole are respectively disposed in the third damping portion body 34310. The third positioning portion 34311 is disposed on an outer periphery of the third damping portion body 34310. The third positioning portion 34311 abuts against an outer surface of the third bracket body 3430. In some embodiments, the third bracket 343 further includes an end cover 3432. The end cover 3432 is disposed on one side of the third bracket 343 and covers the third positioning portion 34311. In this way, it is easy to fix the third damping portion 3431 to the third bracket 343 by the end cover 3432.

In some embodiments, the end cover 3432 includes an avoidance opening, and the third damping portion body 34310 passes through the avoidance opening, so that the ventilation hole is in communication with the outside of the end cover 3432.

In some embodiments, the mounting assembly 34 is disposed on the volute 31, the motor 32 is disposed on the mounting assembly 34, and the rotating shaft 321 of the motor 32 passes through the impeller 33. The mounting assembly 34 is configured to support and fix the motor 32 on one side of the impeller 33. The mounting assembly 34 is further configured to support the free end of the rotating shaft 321 on another side of the impeller 33.

One embodiment of the fan is described above, but the present disclosure is not limited thereto. Another embodiment of the fan is described below.

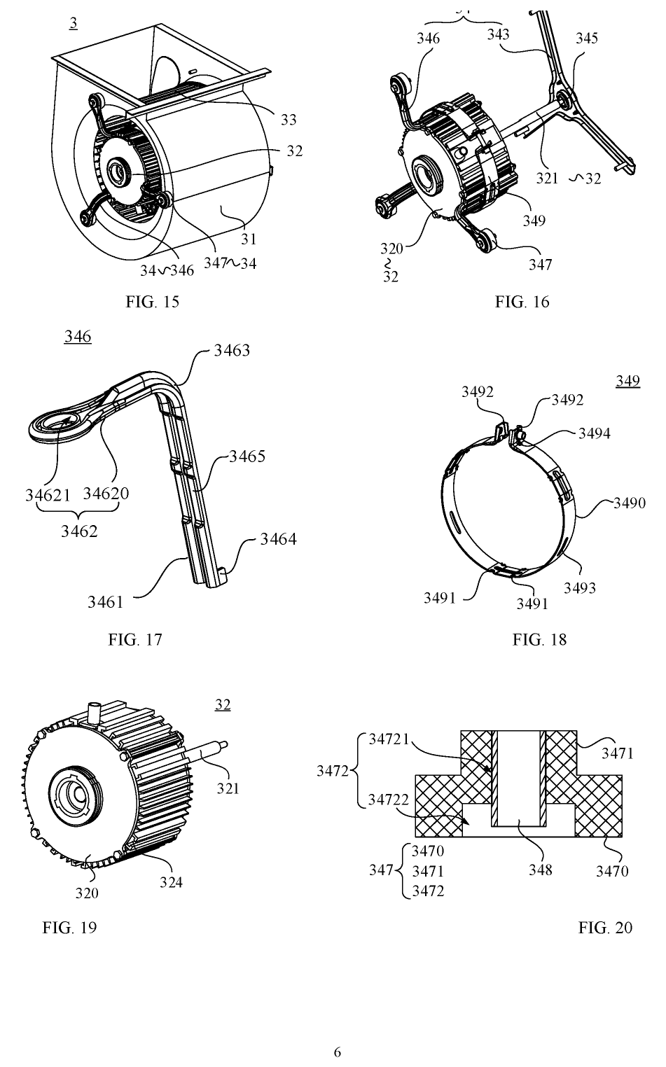

In some embodiments, referring to FIG. 15, the fan 3 includes a volute 31.

In some embodiments, the fan 3 further includes an impeller 33, and the impeller 33 is rotatably disposed in the volute 31.

In some embodiments, the fan 3 further includes a motor 32. The motor 32 is coupled to the impeller 33. The motor 32 is configured to drive the impeller 33 to rotate in the volute 31. The motor 32 includes a motor body 320 and a rotating shaft 321. The rotating shaft 321 is disposed to extend through the impeller 33.

Different from the fan 3 described referring to FIG. 8 to FIG. 14, the motor 32 in FIG. 19 further includes a plurality of mounting portions 324. The plurality of mounting portions 324 are disposed on an outer circumferential surface of the motor body 320 and are spaced apart along a direction surrounding the central axis of the motor body 320.

Referring to FIG. 16, the fan 3 further includes a mounting assembly 34. The motor 32 is fixed to the housing 1 by the mounting assembly 34.

In some embodiments, the mounting assembly 34 includes a plurality of fourth brackets 346 (mounting supports). The fourth bracket 346 is disposed on at least one of the plurality of mounting portions 324 and is connected to one side (e.g., an outer circumferential side) of the volute 31. The plurality of fourth brackets 346 are spaced apart on the exterior of the motor body 320 and are connected to the volute 31, so as to meet support and mounting requirements of the motor body 320.

In some embodiments, the mounting assembly 34 further includes a third bracket 343. The third bracket 343 is disposed on another side of the volute 31 (e.g., a side in an axial direction), and the free end of the rotating shaft 321 of the motor 32 is rotatably disposed on the third bracket 343.

The rotating shaft 321 passes through the impeller 33, and is then connected to the third bracket 343. In this way, the third bracket 343 can support the free end of the rotating shaft 321.

In this way, the motor 32 is mounted onto the volute 31 with the assistance of the mounting assembly 34, the motor body 320 is fixed to the volute 31 by the fourth bracket 346, and the free end of the rotating shaft 321 is supported by the third bracket 343, so that the motor 32 can be reliably supported and fixed by the mounting assembly 34 during transportation of the duct-type air conditioner 1000.

It can be understood that the arrangement of the plurality of fourth brackets 346 can facilitate an operator to adjust a direction and an angle of the motor 32 during assembling, so as to improve stability of mounting among the motor 32, the impeller 33, and the volute 31. The arrangement of the plurality of fourth brackets 346 can also support and fix the motor body 320 at multiple angles, thereby improving reliability of the mounting of the motor 32.

Since the motor 32 may be supported on two sides of the impeller 33, the impeller 33 can also be reliably supported and mounted on the rotating shaft 321 after the assembling of the fan 3 is completed.

During transportation, since the mounting assembly 34 reliably supports the motor 32 on two sides of the impeller 33, changes in a mounting position of the impeller 33 caused by deviation of the motor 32 can be reduced, which is conducive to improving operational reliability of the duct-type air conditioner 1000.

In some embodiments, referring to FIG. 17, the fourth bracket 346 includes a first arm 3461 (a fixing arm). The first arm 3461 is connected to a mounting portion 324 of the motor body 320, and extends along an axial direction of the motor body 320.

In some embodiments, the fourth bracket 346 further includes a second arm 3462 (a support arm). A first end of the second arm 3462 is connected to an end portion (a first end) of the first arm 3461 on a side adjacent to the housing 1, and a second end of the second arm 3462 is connected to the volute 31. In this way, the fourth bracket 346 can be fixedly connected to the volute 31 by the second arm 3462, thereby fixedly connecting the motor body 320 to the volute 31.

In some embodiments, the fourth bracket 346 further includes a second fitting portion 3463 (a mounting fitting portion). The second fitting portion 3463 is disposed on a side of the first arm 3461 adjacent to the mounting portion 324 and extends along a length direction of the first arm 3461. The first arm 3461 is connected to the mounting portion 324 by the second fitting portion 3463.

During the mounting, the second fitting portion 3463 of the first arm 3461 is disposed on the corresponding mounting portion 324, and the second arm 3462 is connected to the volute 31, so as to fixedly connect the motor body 320 to the housing 1.

In some embodiments, the first arm 3461 and the second arm 3462 are at a predetermined included angle. When the included angle between the first arm 3461 and the second arm 3462 is 90 degrees, the fourth bracket 346 as a whole has an L-shaped structure. In this way, the first arm 3461 of the fourth bracket 346 is connected to the motor 32, and the second arm 3462 is fixedly connected to the housing 1, so as to mount the motor body 320 into the volute 31.

It should be noted that the mounting portion 324 and the second fitting portion 3463 may have various structural forms. For example, the mounting portion 324 is a first engaging slot formed on an outer periphery of the motor 32, and the second fitting portion 3463 is a first engaging protrusion formed on the first arm 3461. The first engaging protrusion is engaged into the first engaging slot to achieve mounting of the fourth bracket 346 and the motor 32.

Alternatively, the mounting portion 324 is a second engaging protrusion formed on the outer periphery of the motor 32, and the second fitting portion 3463 is a second engaging slot formed in the first arm 3461. The second engaging protrusion is engaged into the second slot to achieve mounting of the fourth bracket 346 and the motor 32.

In some embodiments, referring to FIG. 17, to position the motor 32 during the mounting, the fourth bracket 346 further includes a first limiting portion 3464 (a limiting protrusion). The first limiting portion 3464 is disposed at an end portion (a second end) of the first arm 3461 away from the second arm 3462. The first limiting portion 3464 may abut against an end face of the motor body 320 away from the second arm 3462.

During assembly, the first arm 3461 may be mounted to the motor 32 first by connecting the second fitting portion 3463 to the mounting portion 324. Then, by adjusting the position of the motor 32, the first limiting portion 3464 abuts against an end face of the motor 32 on a side away from the housing 1. In this way, after being inserted into the end face of the volute 31, the motor 32 can be positioned by the first limiting portion 3464 of the first arm 3461, thereby improving convenience and accuracy of assembling of the motor 32.

In some embodiments, referring to FIG. 16, FIG. 17, and FIG. 20, the second arm 3462 includes a second arm body 34620. The second arm 3462 further includes a fifth hole 34621 (an assembly hole) provided in the second arm body 34620. The fifth hole 34621 is disposed at a second end of the second arm body 34620 away from the first arm 3461. The fourth bracket 346 is assembled to the housing 1 via the fifth hole 34621.

For example, the second arm 3462 and the housing 1 are connected to each other by a connecting bolt and a connecting nut. The connecting bolt passes through the fifth hole 34621 and is fixed to the volute 31 by the connecting nut.

In some embodiments, the mounting assembly 34 further includes a damping assembly. The damping assembly is disposed at a junction between the fifth hole 34621 and the housing 1, to reduce vibration generated by the motor 32 during operation.

In some embodiments, referring to FIG. 16, the damping assembly includes a second damping portion 347 (a damping sleeve). The second damping portion 347 is connected to the second arm 3462 via the fifth hole 34621.

The second damping portion 347 includes a second damping portion body 3470 and a second engaging portion 3471. The second engaging portion 3471 is disposed on a side of the second damping portion body 3470 adjacent to the fifth hole 34621, and is inserted into the fifth hole 34621. In this way, after the second engaging portion 3471 is inserted into the fifth hole 34621, the second damping portion body 3470 can abut against the volute 31, so as to achieve a damping effect.

Referring to FIG. 20, the second damping portion 347 further includes a sixth hole 3472 (a stepped hole). The sixth hole 3472 extends through at least part of the second damping portion body 3470 along an axial direction of the second damping portion body 3470. The sixth hole 3472 includes a first sub-hole 34721 and a second sub-hole 34722 that are in communication with each other. A diameter of the first sub-hole (or referred to as first sub-hole section) 34721 is less than that of the second sub-hole 34722, and at least part of the first sub-hole 34721 extends through the second engaging portion 3471.

In some embodiments, the damping assembly further includes a third fitting portion 348 (a metal sleeve), and the third fitting portion 348 is disposed in the first sub-hole 34721. A connecting bolt passes through the third fitting portion 348 and is fixed to the volute 31 by a connecting nut. In this way, limiting can be enabled under a condition of ensuring damping, which prevents off-center mounting of the impeller 33 of the fan 3, improving assembling precision.

The second damping portion 347 is disposed in the fifth hole 34621 of the second arm 3462, and the third fitting portion 348 is disposed in the sixth hole 3472 that is formed in the second damping portion 347. In this way, during assembling the fourth bracket 346 to the volute 31, the connecting bolt passes through the third fitting portion 348 and is connected to the volute 31, so that the third fitting portion 348 can protect the second damping portion 347, preventing damage to the second damping portion by the connecting bolt. The second arm 3462 is connected to the connecting bolt by the second damping portion 347, so that a good damping effect can be achieved by the second damping portion 347, thereby reducing operating noise of the motor 32.

It can be understood that an end face of the second damping portion 347 adjacent to the second sub-hole 34722 abuts against the volute 31, and the second sub-hole (or referred to as the second sub-hole section) 34722 is spaced apart from the connecting bolt, so that a buffer region is formed between the second sub-hole section 34722 and the volute 31. The buffer region is configured to generate a certain amount of compression when the connecting bolt is mounted into the second damping portion 347 and presses the second damping portion 347, so as to securely mount the connecting bolt to the housing 1.

In some embodiments, the second damping portion 347 is disposed corresponding to the fourth bracket 346. For example, the number of the second damping portions 347 may be equal to that of the fourth brackets 346. To limit the amount of compression of the second damping portion 347, the third fitting portion 348 is disposed inside the second damping portion 347 to limit the amount of compression of the second damping portion 347, which prevents eccentricity of the rotating shaft 321 of the motor 32 caused by different amounts of compression when a plurality of second damping portions 347 are mounted, thereby improving assembling precision and reliability of the fan 3.

In some embodiments, referring to FIG. 16 and FIG. 18, the mounting assembly 34 further includes a locking member 349, and the locking member 349 is disposed around the outer periphery of the motor 32. The locking member 349 is located on outer peripheries of the plurality of fourth brackets 346, and the locking member 349 is configured to lock the plurality of fourth brackets 346 onto the motor 32.

It can be understood that on the exterior of the motor 32, by fastening the fourth brackets 346 onto the motor 32 by the locking member 349, it is conducive to improving reliability of the connection between the fourth bracket 346 and the motor 32.

In some embodiments, the locking member 349 has two end portions with an opening. After the locking member 349 is mounted on the fourth bracket 346, the locking member 349 may abut against the first arm 3461, so that the first arm 3461 is pressed against the motor 32.

In some embodiments, to limit the position of the locking member 349, referring to FIG. 17, the fourth bracket 346 further includes a first positioning portion 3465, and the first positioning portion 3465 is disposed on a side of the first arm 3461 away from the motor body 320. The locking member 349 may be disposed in the first positioning portion 3465. The first positioning portion 3465 is configured to limit the locking member 349, to restrict movement of the locking member 349 along the axial direction of the motor body 320.

In some embodiments, the locking member 349 surrounds the periphery of the motor 32 and is engaged in the first positioning portion 3465 of the corresponding fourth bracket 346 for positioning. This, on the one hand, can improve mounting accuracy of the locking member 349, and on the other hand, can restrict movement of the locking member 349 along an axial direction of the motor 32.

In some embodiments, referring to FIG. 18, the locking member 349 includes a locking member body 3490 and a plurality of pairs of second positioning portions 3491. The second positioning portion 3491 is disposed on a side surface (e.g., an inner surface) of the locking member body 3490 adjacent to the fourth bracket 346. The second positioning portion 3491 is configured to restrict rotation of the locking member body 3490 along a circumferential direction of the motor 32.

For example, a positioning region is formed between two adjacent second positioning portions 3491, and the fourth bracket 346 is located in a corresponding positioning region.

In this way, by disposing the plurality of pairs of second positioning portions 3491 on an inner surface of the locking member 349 and arranging two adjacent second positioning portions 3491 on two sides of the first arm 3461, respectively, the position of the locking member 349 can be further limited, and assembling efficiency of the locking member 349 can be improved.

In summary, through the arrangement of the first positioning portion 3465 and the second positioning portion 3491, the motor can be limited in the axial direction and the circumferential direction respectively, thereby forming crosswise limiting between the fourth bracket 346 and the locking member 349, which facilitates mounting and fixing of the locking member 349.

In some embodiments, to facilitate tightening of the locking member 349, the locking member 349 further includes two extension portions 3492 (curved portions). The two extension portions 3492 are respectively disposed at two end portions of the locking member body 3490, and the two extension portions 3492 extend outwards. One of the two extension portions 3492 is provided with a through hole, and the other of the two extension portions 3492 is provided with a fastening nut. A fastening bolt passes through the through hole and is threadedly connected into the fastening nut.

In this way, by tightening the extension portions 3492 at two end portions of the locking member 349 by the fastening bolt, the extension portions 3492 at the two end portions of the locking member 349 abut against each other, to achieve locking of the locking member 349.

In some embodiments, referring to FIG. 18, the locking member 349 further includes a plurality of seventh holes 3493 (stress relief holes). The plurality of seventh holes 3493 are arranged in sequence along a circumferential direction of the locking member body 3490. For example, the seventh hole 3493 may extend along a direction surrounding an axis of the locking member.

It can be understood that, since the locking member 349 has an arc-shaped structure, by designing the seventh holes 3493 on the two sides of the locking member 349, the arc-shaped structure of the locking member 349 can be prevented from springing back.

In some embodiments, the locking member 349 further includes a plurality of reinforcing ribs 3494. The plurality of reinforcing ribs 3494 are arranged in sequence along a circumferential direction of the locking member body 3490. At least one of the plurality of reinforcing ribs 3494 extends along a direction parallel to an axis of the locking member body 3490, which can improve strength of the locking member 349.

In some embodiments, the reinforcing rib 3494 may alternatively be formed between the extension portion 3492 and the locking member body 3490, so as to further enhance structural strength of the extension portion 3492 and prevent deformation of the extension portion 3492.

In some embodiments, referring to FIG. 16, the mounting assembly 34 further includes a bearing 345. The bearing 345 is disposed in the third bracket 343. The free end of the rotating shaft 321 of the motor 32 is inserted into the bearing 345.

It should be noted that the method by which the third bracket 343 is provided with the bearing 345 to mount the rotating shaft 321 of the motor 32 is similar to that in the foregoing embodiments, which is not repeatedly described in detail herein again.

In some embodiments, when the motor 32 is assembled by the mounting assembly 34, the impeller 33 may be arranged between the fourth bracket 346 and the third bracket 343 of the mounting assembly 34, and the fourth bracket 346 and the third bracket 343 are respectively disposed on the volute 31. The fourth bracket 346 is configured to support and fix the motor body 320 on one side of the impeller 33, and the third bracket 343 is configured to support the free end of the rotating shaft 321 of the motor 32 on another side of the impeller 33.

In this way, the fourth bracket 346 and the third bracket 343 are respectively disposed on the two sides of the impeller 33 to support the motor body 320 and the free end of the rotating shaft 321, thereby achieving the mounting of the motor 32.

It should be noted that any of technical solution disclosures in the present disclosure can solve one or more of the above technical problems to some extent and achieve a certain invention object. Alternatively, a plurality of technical disclosures may be combined into an integral solution to solve one or more of the above technical problems and achieve a certain invention object. Alternatively, part of the technical disclosures may be selected to be combined into an integral solution, meanwhile, related technologies and inferior solutions are used, but the deteriorating trend can be remedied through means in these technical disclosures, thereby solving one or more of the above technical problems to some extent and achieving a certain invention object as a whole. Each technical disclosure is combined into a complete technical solution and forms an organic indivisible integral solution, to solve the technical problems and achieve a certain invention object as a whole.

Any of technical disclosures in the present disclosure as well as recombinations of the plurality of technical disclosures that can form a complete technical solution, can solve one or more of the plurality of technical problems and achieve the invention object, belongs to the content of the present disclosure, and belongs to the content determined directly and unambiguously according to the content of the present disclosure.

Those skilled in the art should understand that the disclosure scope of the present disclosure is not limited to the above specific embodiments, and some elements of the embodiments can be modified and replaced without departing from the spirit of the present disclosure. The scope of the present disclosure is limited by the appended claims.

What is claimed is:

1. An air conditioner, comprising: an outdoor unit; and an indoor unit connected to the outdoor unit, and comprising: a housing comprising an air inlet and an air outlet; a heat exchange assembly comprising: a heat exchanger configured to exchange heat with an airflow flowing therethrough to form a heat-exchange airflow; and a drain pan disposed on one side of the heat exchanger; the drain pan being configured to collect water generated on a surface of the heat exchanger; a fan configured to drive the airflow to enter the housing via the air inlet to exchange heat with the heat exchanger, and to send out the airflow after heat exchange via the air outlet; and an electrical control assembly comprising: an electrical control box; and a circuit board disposed in the electrical control box; wherein the heat exchange assembly, the fan, and the electrical control box are respectively disposed in the housing; and along an airflow flow direction inside the housing, the heat exchange assembly and the electrical control box are arranged in sequence; wherein the electrical control box comprises an electrical control box body and a diversion surface, wherein the diversion surface is disposed on the electrical control box body and arranged facing the drain pan; and the diversion surface is obliquely disposed in the housing.

2. The air conditioner according to claim 1, wherein the electrical control box body comprises: a box body disposed in the housing, and the circuit board being disposed in the box body; and a cover detachably connected to the box body; wherein at least one of the box body or the cover is provided with the diversion surface, and the diversion surface is configured to divert water overflowing from the drain pan when the housing is in an upright state.

3. The air conditioner according to claim 2, wherein at least one of the following is further satisfied: when the box body is provided with the diversion surface, the box body is arranged obliquely, and the diversion surface is disposed on an outer surface of the box body; when the housing is in the upright state, the diversion surface is located on a side of the drain pan away from the heat exchanger; and along a direction away from the drain pan, the diversion surface extends obliquely towards a direction away from an inner wall of the housing; when the cover is provided with the diversion surface, the cover is arranged adjacent to an inner wall of the housing; and the electrical control box further comprises a first shielding portion, one end of the first shielding portion being connected to an end portion of the cover adjacent to the drain pan, and another end of the first shielding portion extending obliquely away from the inner wall of the housing and towards a direction approaching the drain pan; wherein the first shielding portion is located between the box body and the drain pan, and the diversion surface is disposed on a surface of the first shielding portion facing the drain pan; and when the housing is in the upright state, the first shielding portion is located below a drain outlet of the drain pan, and the first shielding portion shields a side edge of the box body adjacent to the drain pan.

4. The air conditioner according to claim 2, wherein the box body comprises: a first plate, the diversion surface being disposed on an outer surface of the first plate, and the circuit board being disposed on an inner surface of the first plate; and a second plate disposed on each of two side portions of the first plate, and the second plate extending towards a direction away from the drain pan; wherein at least one of the first plate and the second plate is disposed in the housing.

5. The air conditioner according to claim 4, wherein the electrical control box further comprises a heat dissipation opening disposed in the first plate; and
the electrical control assembly further comprises a heat dissipation portion located at the heat dissipation opening; the heat dissipation portion being inserted into the heat dissipation opening to close the heat dissipation opening, and the heat dissipation portion being in thermal conductive connection with the circuit board.

6. The air conditioner according to claim 5, wherein the electrical control box further comprises a water blocking portion disposed on the first plate, wherein the water blocking portion protrudes from the diversion surface; the water blocking portion is arranged on an outer side of the heat dissipation portion and configured to block water for the heat dissipation portion; wherein the water blocking portion satisfies one of the following: the water blocking portion has an annular structure, and the water blocking portion is arranged around a periphery of the heat dissipation opening; and the water blocking portion comprises a first sub water blocking portion, a second sub water blocking portion, and a third sub water blocking portion, wherein ends of the first sub water blocking portion and the second sub water blocking portion that are adjacent to each other are connected to each other, ends of the second sub water blocking portion and the third sub water blocking portion that are adjacent to each other being connected to each other; and the first sub water blocking portion and the third sub water blocking portion are spaced apart to form an opening, the opening being disposed away from the drain pan.

7. The air conditioner according to claim 5, wherein at least one of the following is further satisfied: the electrical control box further comprises a sealing plat covering the diversion surface, and the heat dissipation portion is connected to the heat dissipation opening by the sealing plate; and the electrical control box further comprises: a first hole disposed in the first plate; and a wiring portion disposed in the first hole.

8. The air conditioner according to claim 1, further comprising a mounting bracket disposed in the housing, wherein the mounting bracket comprises: a mounting bracket body; a mounting surface located on a side of the mounting bracket body adjacent to the heat exchange assembly, wherein the electrical control box and the fan are disposed on the mounting surface; and a vent disposed on the mounting surface, the fan being in communication with the vent;
wherein the electrical control box and the fan are located between the mounting bracket and the heat exchange assembly.

9. The air conditioner according to claim 8, wherein at least one of the following is further satisfied: the diversion surface is adjacent to the fan; or the housing further comprises a diversion cover disposed at the vent, and a sectional area of the diversion cover gradually increasing along an air outlet direction.

10. The air conditioner according to claim 1, wherein the fan comprises: a volute; an impeller rotatably disposed in the volute; a motor connected to the impeller and configured to drive the impeller to rotate in the volute; the motor comprising: a motor body; and a rotating shaft, a first end of the rotating shaft being connected to the motor body, and a second end of the rotating shaft extending through the impeller; and a mounting assembly, the motor and the impeller being disposed in the volute by the mounting assembly; wherein the mounting assembly comprises: a first bracket disposed on one side of the volute and configured to support the motor body; a second bracket connected to the first bracket; the motor body being disposed between the first bracket and the second bracket; and a third bracket disposed on another side of the volute and arranged opposite to the first bracket; and the second end of the rotating shaft being disposed on the third bracket.

11. The air conditioner according to claim 10, wherein the first bracket comprises: a first bracket body; a bracing portion disposed on the first bracket body, and the motor body being disposed on the bracing portion; a first engaging portion disposed at a first end of the bracing portion; and a second hole disposed at a second end of the bracing portion; wherein the second bracket comprises: a second bracket body; a first fitting portion disposed at a first end of the second bracket body; the first engaging portion cooperating with the first fitting portion to engage a first end of the first bracket with a first end of the second bracket; and a third hole disposed at a second end of the second bracket body; a second end of the first bracket and the second end of the second bracket being fixedly connected via the second hole and the third hole.

12. The air conditioner according to claim 11, wherein the motor assembly further comprises a first damping portion, wherein one side of the first damping portion abuts against an end portion of the motor body, and another side of the first damping portion is clamped by the first bracket and the second bracket; and
the mounting assembly further comprises: a first reinforcing member connected to two sides of the first bracket; and a bearing disposed on the third bracket; a free end of the rotating shaft being disposed on the bearing, so as to be rotatably connected to the third bracket.

13. The air conditioner according to claim 1, wherein the fan comprises: a volute; an impeller rotatably disposed in the volute; a motor connected to the impeller and configured to drive the impeller to rotate in the volute; the motor comprising: a motor body; and a rotating shaft, a first end of the rotating shaft being connected to the motor body, and a second end of the rotating shaft extending through the impeller; and a plurality of mounting portions spaced apart around a periphery of the motor body.

14. The air conditioner according to claim 13, wherein the motor further comprises a mounting assembly, wherein the motor is disposed in the volute by the mounting assembly; and the mounting assembly comprises: a third bracket connected to the volute, and a free end of the rotating shaft being disposed on the third bracket; and a plurality of fourth brackets, a first end of any one of the plurality of fourth brackets being connected to a respective one of the plurality of the mounting portions, and a second end of any one of the plurality of fourth brackets being connected to the volute, to fix the motor body to the volute.

15. The air conditioner according to claim 14, wherein the fourth bracket comprises: a first arm connected to the mounting portion; and a second arm, a first end of the second arm being connected to the first arm, and a second end of the second arm being connected to the volute; a second fitting portion disposed on a side of the first arm adjacent to the mounting portion and extending along a length direction of the first arm; and a first limiting portion disposed at an end of the first arm away from the second arm and configured to abut against an end face of the motor body away from the second arm, to restrict movement of the first arm along an axial direction of the motor body.

16. The air conditioner according to claim 15, wherein the second arm comprises: a second arm body connected to the first arm; and a fifth hole disposed at an end of the second arm body away from the first arm, the second arm being connected to the volute via the fifth hole; wherein the fourth bracket further comprises a damping assembly disposed in the fifth hole; and the damping assembly comprising: a second damping portion disposed in the fifth hole; the second damping portion comprising: a second damping portion body; and a second engaging portion disposed on a side of the second damping portion body adjacent to the fifth hole and engaged into the fifth hole; a sixth hole disposed in the second damping portion; the sixth hole comprising: a first sub-hole section provided in the second engaging portion; and a second sub-hole section, a diameter of the first sub-hole section being less than that of the second sub-hole section; and a third fitting portion disposed in the first sub-hole section, the fourth bracket being fixed to the volute by the third fitting portion.

17. The air conditioner according to claim 15, wherein the mounting assembly further comprises a locking member disposed on an outer periphery of the fourth bracket, and the locking member being configured to fasten the fourth bracket to the motor body;
wherein the fourth bracket further comprises a first positioning portion disposed on a side of the first arm away from the motor body; and the locking member is disposed on the first positioning portion, and the first positioning portion is configured to restrict movement of the locking member along the axial direction of the motor body; wherein the locking member comprises: a locking member body; and a second positioning portion disposed on a side adjacent to the fourth bracket; wherein the fourth bracket being disposed on the second positioning portion, and the second positioning portion is configured to restrict movement of the locking member along a circumferential direction of the motor body.

18. The air conditioner according to claim 17, wherein the locking member further comprises: extension portions respectively disposed on two ends of the locking member body, and the locking member being tightened by pulling the extension portions to tighten the locking member body; a seventh hole arranged along a circumferential direction of the locking member body, the seventh hole being configured to eliminate stress on the locking member body; and a plurality of reinforcing ribs arranged in sequence along the circumferential direction of the locking member body, and any one of the plurality of reinforcing ribs extending along a width direction of the locking member body, to improve strength of the locking member.

19. The air conditioner according to claim 13, wherein the mounting assembly further comprises a bearing disposed in the third bracket; and a free end of the rotating shaft is disposed on the bearing, and is rotatably connected to the third bracket by the bearing.

20. An air conditioner, comprising; an outdoor unit; and an indoor unit connected to the outdoor unit, and comprising: a housing comprising an air inlet and an air outlet; a heat exchange assembly comprising: a heat exchanger configured to exchange heat with an airflow flowing therethrough to form a heat-exchange airflow; and a drain pan disposed on one side of the heat exchanger; a fan configured such that the airflow is introduced through the air inlet, passes through the heat exchanger, and is then sent out from the air outlet; an electrical control assembly comprising an electrical control box and a circuit board, the circuit board being disposed in the electrical control box; and wherein the heat exchange assembly, the fan, and the electrical control box are disposed in the housing, and along an airflow flow direction inside the housing, the heat exchange assembly and the electrical control box are arranged in sequence;
wherein the housing further comprises: a second shielding portion disposed inside the housing and protruding and extending obliquely from an inner wall of the housing, and the second shielding portion being located between the electrical control box and the drain pan; and a diversion surface disposed on a surface of the second shielding portion facing the drain pan; wherein when the housing is in an upright state, the second shielding portion is located below a drain outlet of the drain pan, and the second shielding portion shields a side edge of the electrical control box adjacent to the drain pan.
